(19) United States
(12) Patent Application Publication
(10) Pub. No.: US 2024/0107715 A1
(43) Pub. Date: Mar. 28, 2024

(54) Maximizing Server Density in a Two-Phase Immersion Cooling System for a Data Center

(71) Applicant: QUANTA ASSOCIATES, L.P., Houston, TX (US)

(72) Inventor: Todd Richard, University Park, FL (US)

(21) Appl. No.: 18/472,501

(22) Filed: Sep. 22, 2023

Related U.S. Application Data
(60) Provisional application No. 63/377,110, filed on Sep. 26, 2022.

(51) Int. Cl. H05K 7/20; H05K 7/14

(52) U.S. Cl. CPC H05K 7/208; H05K 7/1487; H05K 7/1489; H05K 7/203; H05K 7/20327

(57) ABSTRACT

A two-phase immersion cooling system for a data center for maximizing server density has a rectangular tank with four bays mounted in the tank, a volume of two-phase immersion cooling fluid, a circulating system for the two-phase immersion cooling fluid, and a cooling system for the two-phase immersion cooling fluid. Each bay has a guide rail system defining eighteen guide rails mounted in parallel. Seventy-two server blades are mounted via the guide rails across all four bays. Each of the server blades defines a gap between adjacent server blade(s), and servers mounted on each blade. Each guide rail is mounted having one of two longest dimensions vertically positioned and another mounted perpendicular to the direction of two relatively shorter sidewalls of the tank.

### CROSS-REFERENCE TO RELATED APPLICATIONS

Not Applicable.

### STATEMENTS REGARDING FEDERALLY SPONSORED RESEARCH OR DEVELOPMENT

Not Applicable.

### NAMES OF THE PARTIES TO A JOINT RESEARCH AGREEMENT

Not Applicable.

### BACKGROUND

Technical field: The subject matter generally relates to apparatus and techniques for cloud-based services and, more specifically, datacenters. The related power, and hence, heat dissipation from servers and chips continues to increase. Hence, the need exists for improved cooling systems.

Standard or traditional datacenters have utilized air cooling to maintain appropriate operating temperatures. Such datacenters require a relatively large square footage or footprint, have relatively large energy needs, and may not accommodate high computing power or hardware for process-intensive applications efficiently.

Cooling fluid for liquid cooling of electronics and datacenter components applications can be very costly because the greater the volume of fluid, the higher the cost. There is a need to solve issues related to cooling and power dissipation of electronics and datacenter components using cooling fluid for liquid cooling. These systems may be made modular to contain the electronics in the volume of cooling needed for sufficient cooling.

### BRIEF SUMMARY

The present disclosure generally relates to embodiments of an apparatus for two-phase fluid immersion cooling of a plurality of servers in a datacenter facility.

Additionally, the present disclosure relates to embodiments of a modular apparatus for two-phase fluid immersion cooling of a plurality of servers in a datacenter facility.

Additionally, the present disclosure relates to embodiments of methods of maximizing server density and decreasing the footprint of a data center.

A two-phase immersion cooling system for a data center for maximizing server density has a rectangular tank with four bays mounted in the tank, a volume of two-phase immersion cooling fluid, a circulating system for the two-phase immersion cooling fluid, and a cooling system for the two-phase immersion cooling fluid. Each bay has a guide rail system defining eighteen guide rails mounted in parallel. Seventy-two server blades are mounted in the guide rails across all four bays. Each of the server blades defines a gap between adjacent server blade(s), and servers mounted on each blade. Each guide rail is mounted having one of two longest dimensions vertically positioned and another mounted perpendicular to the direction of two relatively shorter sidewalls of the tank.

### BRIEF DESCRIPTION OF THE DRAWINGS

The embodiments may be better understood, and numerous objects, features, and advantages made apparent to those skilled in the art by referencing the accompanying drawings. These drawings are used to illustrate only typical embodiments of this disclosure, and are not to be considered limiting of its scope, for the disclosure may admit to other equally effective embodiments. The figures are not necessarily to scale and certain features and certain views of the figures may be shown exaggerated in scale or in schematic in the interest of clarity and conciseness.

FIG. 1 depicts a top view schematic layout of an exemplary embodiment of a data center facility having two-phase fluid immersion cooling tanks.

FIG. 2 depicts a perspective view of an exemplary embodiment of a two-phase fluid immersion cooling tank.

FIG. 3A depicts a perspective view of an exemplary embodiment of a two-phase fluid immersion cooling tank.

FIG. 3B depicts a top view of an exemplary embodiment of a two-phase fluid immersion cooling tank.

FIG. 3C depicts a left side view of an exemplary embodiment of a two-phase fluid immersion cooling tank having a relatively shorter sidewall removed.

FIG. 3D depicts a front elevation view of an exemplary embodiment of a two-phase fluid immersion cooling tank.

FIG. 3E depicts a right-side view of an exemplary embodiment of a two-phase fluid immersion cooling tank having housing removed.

FIG. 4A depicts a top cross-sectional view of an exemplary embodiment of the two-phase fluid immersion cooling tank taken from FIG. 4B along section line 4A-4A.

FIG. 4B depicts a front elevation view of an exemplary embodiment of a two-phase fluid immersion cooling tank.

FIG. 4C depicts a side cross-sectional view of an exemplary embodiment of a two-phase fluid immersion cooling tank taken from FIG. 4B along section line 4C-4C.

FIG. 5 depicts a schematic perspective view of an exemplary embodiment of eighteen server blades mounted in a bay.

FIG. 6 depicts a top view of a blade having outwardly projecting first and second tracks for sliding into a bay via the guide rail system.

FIG. 7 depicts a partial perspective view of an exemplary embodiment of a blade.

FIG. 8 depicts a schematic top view of an exemplary embodiment of a blade containing four servers.

### DETAILED DESCRIPTION OF THE EMBODIMENT(S) SHOWN

The description that follows includes exemplary apparatus, methods, techniques, and instruction sequences that embody techniques of the inventive subject matter. However, it is understood that the described embodiments may be practiced without these specific details.

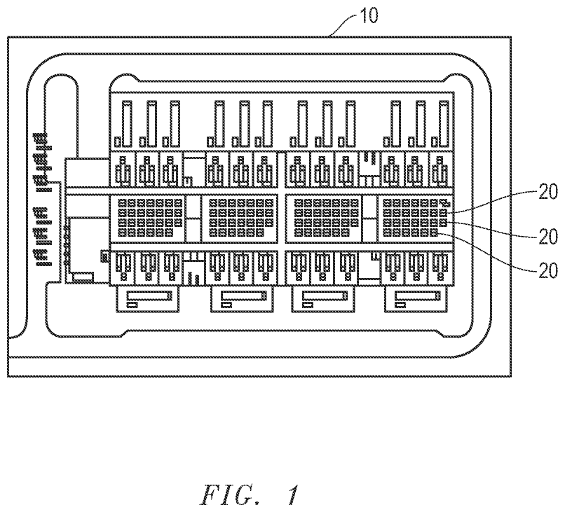

FIG. 1 depicts a top view schematic layout of an exemplary embodiment of a data center facility 10 having two-phase fluid immersion cooling tanks 20. A data center facility 10 having two-phase fluid immersion cooling tanks 20 may have a smaller footprint with a lower cost of construction and energy demand during operations as compared to a traditional data center. By way of example only, a data center facility 10 may have a footprint which is about one quarter of that of a traditional data center. In an exemplary embodiment of a cooling tank 20, it is an objective to increase or maximize the density of the servers 70 (shown in FIG. 5) packed per square foot of tank 20 and/or volume of tank 20 to increase the number of servers 70 as much as possible. In an exemplary embodiment of a cooling tank 20, it is an objective to increase or maximize the density of servers 70 in a volume of immersion cooling fluid 80.

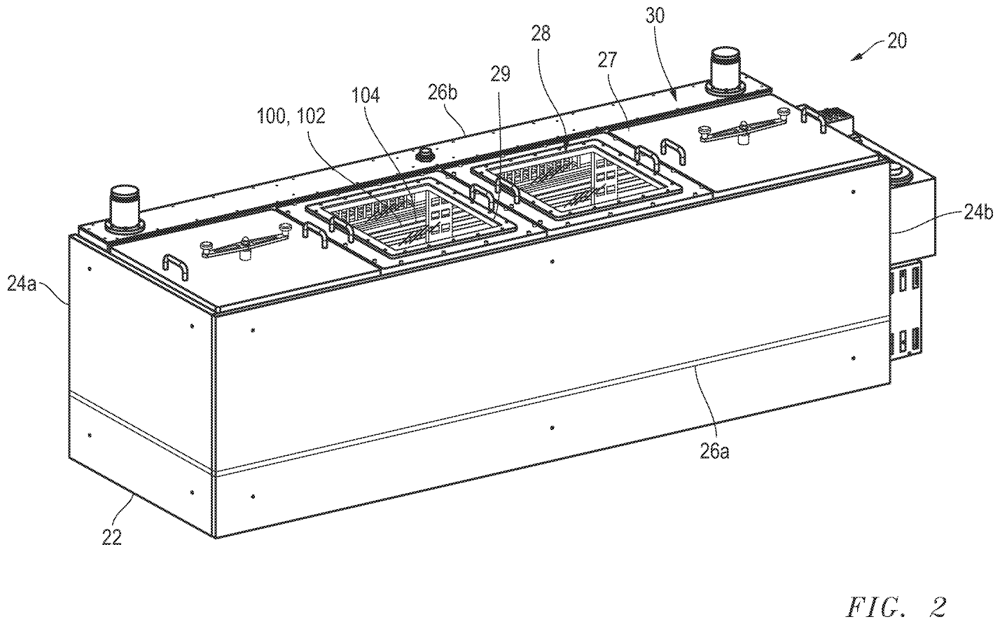

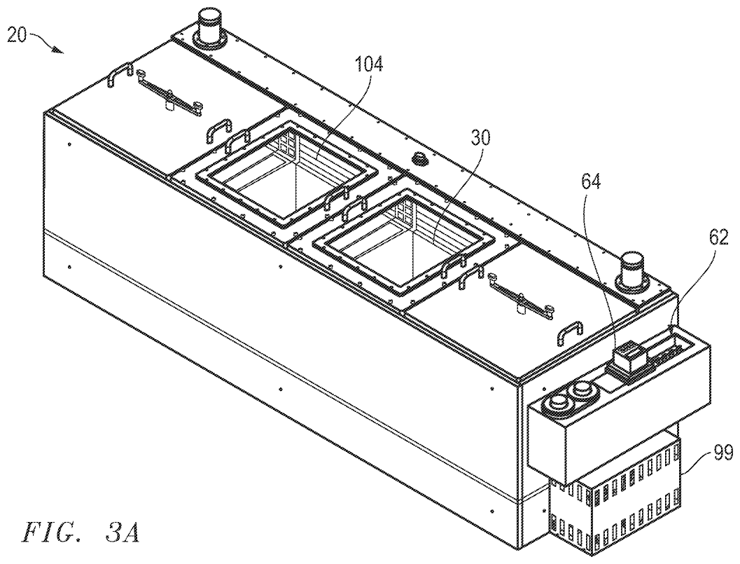

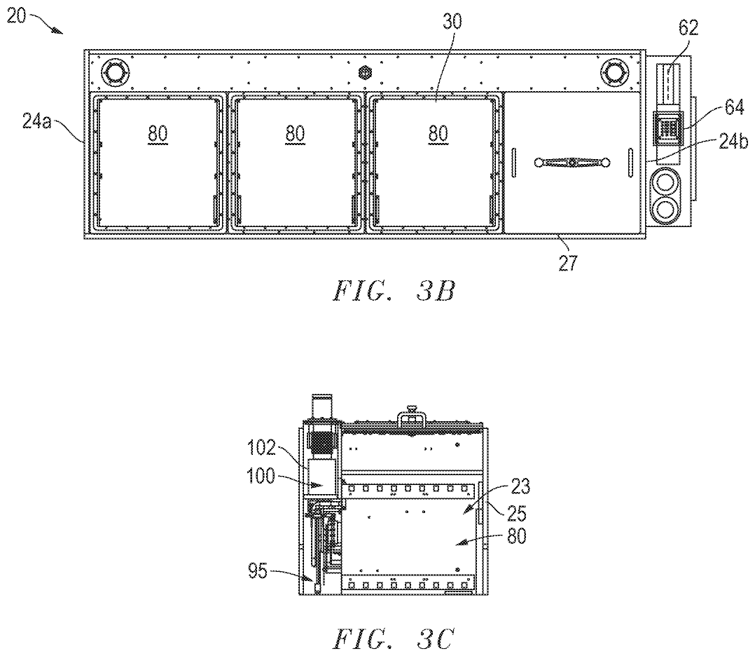

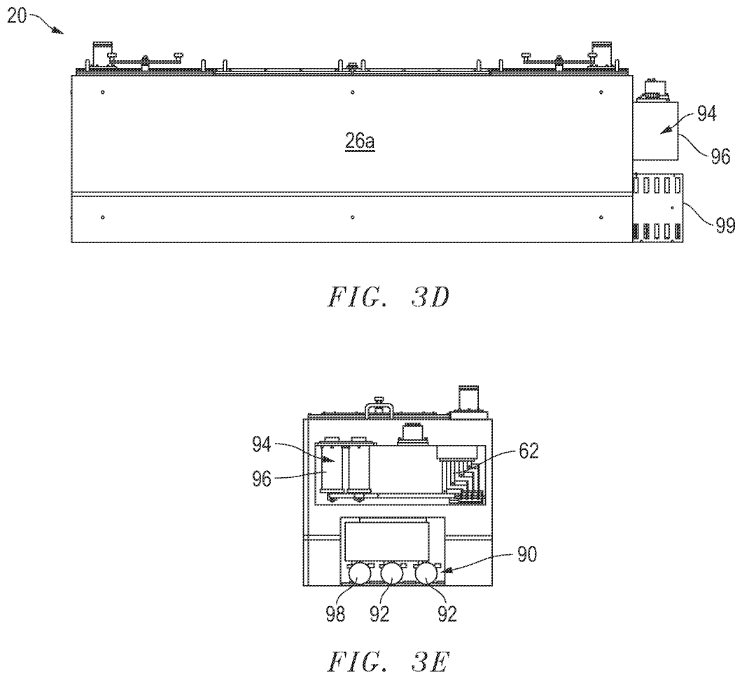

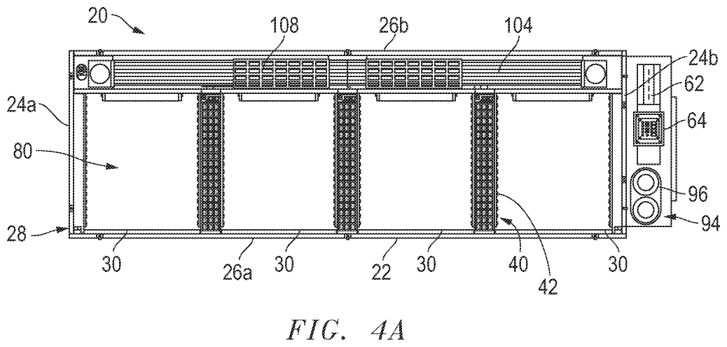

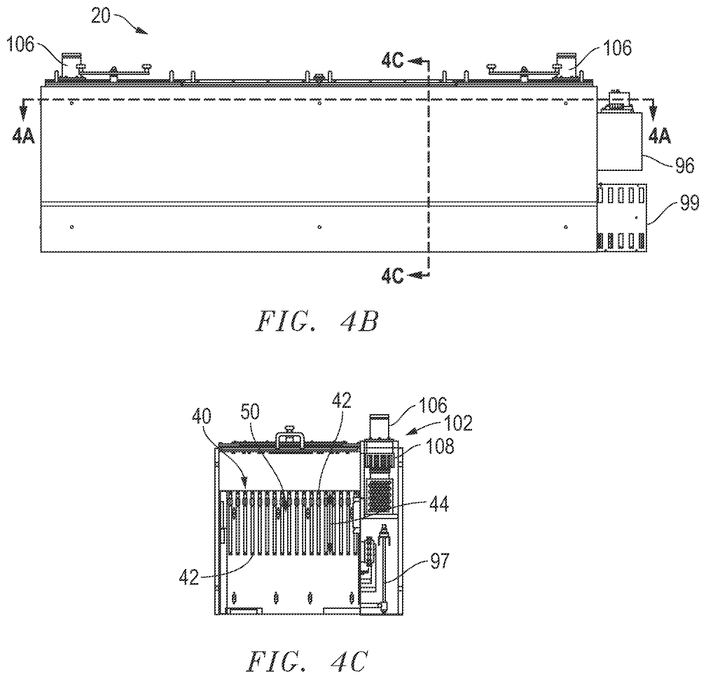

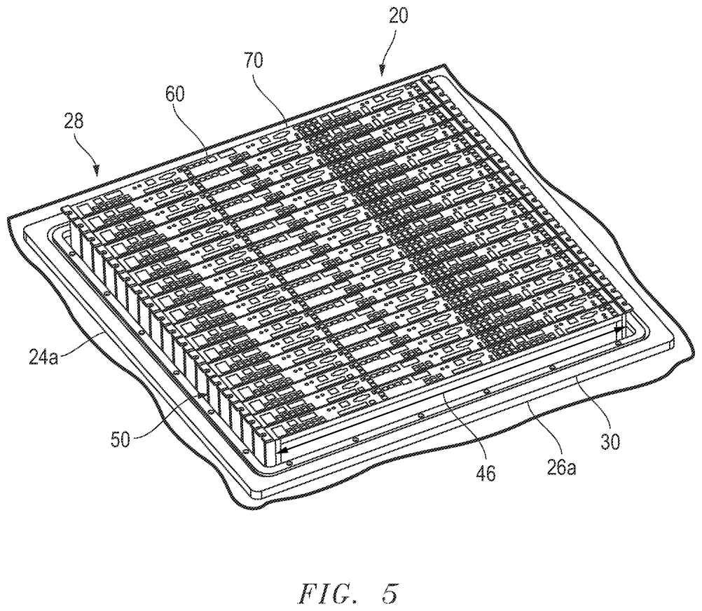

FIG. 2 depicts a perspective view of an exemplary embodiment of a two-phase fluid immersion cooling tank 20. Referring to FIG. 2, and also FIGS. 1, and 3A-5, an apparatus for two-phase fluid immersion cooling of a plurality of servers 70 in a datacenter facility 10 (shown in FIG. 1) may comprise a tank 20. The tank 20 may comprise a rectangular base 22 and four sidewalls 24a, 24b, 26a, 26b (shown in FIG. 2 and FIG. 4A) perpendicular to the base, wherein two of the four sidewalls are relatively shorter sidewalls 24a, 24b, wherein the four sidewalls form a rectangular shaped compartment, and wherein the four sidewalls define a top-side opening 28. Four bays 30 may be mounted in the rectangular shaped compartment of the tank 20. A guide rail system 40 (shown in FIGS. 4A and 4C) may be mounted in each of the four bays 30, wherein each of the guide rail systems 40 comprises eighteen guide rails or bars 42 mounted on each of two opposite inner surfaces of each bay 30, wherein each of the eighteen guide rails or bars 42 on the opposite inner surface of the bays 30 is mounted having one of two longest dimensions 44 vertically positioned and another of the two longest dimensions 46 (see FIG. 5) is mounted perpendicular to the direction of the two relatively shorter sidewalls 24a, 24b, wherein each of the eighteen guide rails 42 is mounted in parallel to an adjacent guide rail 42. By way of example only, each bay 30 may have a hatch door or door 27 and/or window 29 mounted to tank 20. Seventy-two server blades 60 (shown in FIG. 5) may each be separately and respectively mounted in each of the guide rails 42, wherein each of the server blades defines a gap 50 (shown in FIG. 4C and FIG. 5) between the adjacent server blades 60. The gap 50 defined by each of the server blades may be about a 1.0-millimeter gap. By way of example only, one to four servers 70 (preferably four servers 70) may be mounted on each of the seventy-two server blades 60. A volume of a two-phase immersion cooling fluid 80 (shown in FIG. 3B, FIG. 3C, and FIG. 4A) may be in each of the four bays 30 wherein each of the eighteen server blades per bay is immersed in the volume of two-phase immersion cooling fluid 80. By way of example only, a two-phase immersion cooling fluid may be a dielectric thermal management fluid. A tank 20 may further comprise a circulating system 90 (shown in FIG. 3E). The circulating system 90 (shown in FIG. 3E) may comprise a circulation pump 92 mounted to the tank for circulating the volume of two-phase immersion cooling fluid 80, and a filtration system 94 mounted to the tank for filtering the volume of two-phase immersion cooling fluid 80. A tank 20 may further comprise a cooling system 100 (shown in FIG. 3C). A cooling system 100 (shown in FIG. 3C) may comprise a condensing system 102 mounted inside the rectangular shaped compartment of the tank 20 and above the volume of two-phase immersion cooling fluid 80 in each of the four bays 30. By way of example only, condensing system 102 may comprise condenser tubing 104. By way of example only, condensing system 102 may comprise condenser 106 (shown in FIG. 4B and FIG. 4C). By way of example only, condensing system may comprise desiccant tray 108 (shown in FIG. 4A and FIG. 4C).

FIG. 3A depicts a perspective view of an exemplary embodiment of a two-phase fluid immersion cooling tank 20 having bays 30 and condenser tubing 104. Bus bars 62 may convey or communicate data and/or distribute electrical power. Pump cover 99 may be mounted to tank 20. A network/sensor pass through connection (e.g., fiber optic duplex connectors, sensor connections, connectors for Ethernet twisted pair cables) 64 may be mounted to tank 20.

FIG. 3B depicts a top view of an exemplary embodiment of a two-phase fluid immersion cooling tank 20 where three of the four bays 30 are shown without a door or lid. A volume of a two-phase immersion cooling fluid 80 may be contained in and/or flowing through each of the four bays 30. A bay may have a hatch door 27. Tank 20 may have two relatively shorter sidewalls 24a, 24b. Bus bars 62 may convey or distribute data and/or electrical power. Network/sensor pass through 64 may be mounted to tank 20. The volume of a two-phase immersion cooling fluid 80 may be a thermally conductive dielectric liquid or coolant. In an exemplary embodiment the tank 20 may incorporate independent SMP (symmetric multiprocessing) power supply per server blade 60.

FIG. 3C depicts a left side view of an exemplary embodiment of a two-phase fluid immersion cooling tank 20 having a relatively shorter sidewall 24a removed. Cooling system 100 may comprise a condensing system 102. Two-phase immersion cooling fluid 80 may be in the main tank fluid area 23. Reservoir tank 95 may be a reservoir for fluid 80. There may be an insulated panel or panel 25 mounted to tank 20. By way of example only, tank 20 capacity may be about 463.5 gallons without equipment displacement, if filled to a depth of 28 inches. By way of example only, reservoir tank 95 may operate or be run at about 15% to 20% capacity of main tank, which may be seventy to ninety-three gallons at a ten-to-thirteen-inch depth.

FIG. 3D depicts a front view of an exemplary embodiment of a two phase fluid immersion cooling tank 20 and showing sidewall 26a of tank 20. Filtration system 94 may have a filter or dual filter 96. Pump cover 99 may be mounted to tank 20.

FIG. 3E depicts a right-side view of an exemplary embodiment of a two-phase fluid immersion cooling tank 20 having housing removed. Tank 20 may comprise a circulating system 90. Circulating system 90 may comprise one or more circulation pump 92 mounted to the tank for circulating a volume of two-phase immersion cooling fluid 80. Circulating system 90 may comprise a filtration system 94 mounted to the tank 20 for filtering the volume of two-phase immersion cooling fluid 80. Filtration system 94 may have a filter or dual filter 96 and filter pump 98.

FIG. 4A depicts a top cross-sectional view of an exemplary embodiment of the two-phase fluid immersion cooling tank 20 taken from FIG. 4B along section line 4A-4A. The tank 20 comprises a rectangular base 22 and four sidewalls 24a, 24b, 26a, and 26b perpendicular to base 22, wherein two of the four sidewalls are relatively shorter sidewalls 24a, 24b. Four bays 30 are mounted in the rectangular shaped compartment 28 of the tank. A volume of two-phase immersion cooling fluid 80 is contained in each of the four bays 30 and may flow between the bays 30 utilizing the circulating system 90. The tank may have bus bars 62, network/sensor pass thru 64, filter or dual filter 96, and filtration system 94.

FIG. 4B depicts a front view of an exemplary embodiment of a two-phase fluid immersion cooling tank 20. Tank 20 has condenser 106. Pump cover 99 may be mounted to tank 20. Tank 20 may have filter or dual filter 96.

FIG. 4C depicts a side cross-sectional view of an exemplary embodiment of a two-phase fluid immersion cooling tank 20 taken from FIG. 4B along section line 4C-4C. A guide rail system 40 may be mounted in each of the four bays 30. Each guide rail system 40 may comprise eighteen guide rails or bars 42 mounted on each of two opposite inner surfaces of each bay 30, wherein each of the eighteen guide rails or bars 42 on the opposite inner surface of the bays 30 is mounted having one of the two longest dimensions 44 vertically positioned and another of the two longest dimensions 46 (shown in FIG. 5) is mounted perpendicular to the direction of the two relatively shorter sidewalls 24a, 24b, wherein each of the eighteen guide rail slots 42 is mounted in parallel to an adjacent guide rail 42. Spacing or gap 50 between blades 60 (not shown) when engaged with or placed in guide rails 42 may be 1 mm. Reservoir tank 95 may have reservoir tank level or reservoir level sensor 97, which may be a part of the circulating system 90. Sensor 97 may aid in maintaining an appropriate operating volume of fluid 80 in a tank 20. Condensing system 102 may comprise condenser tubing 104 (shown in FIG. 4A), condenser 106, and desiccant tray 108.

FIG. 5 depicts a perspective view of an exemplary embodiment of eighteen server blades 60 being mounted in a bay 30 in a partially depicted tank 20 in the top side opening 28. Eighteen server blades 60 may be mounted in each bay 30 of a tank 20, such that seventy-two blades 60 are mounted in a tank 20. Each server blade 60 may be separately and respectively mounted in each of the guide rails 42, wherein each of the server blades defines a gap 50 between adjacent server blades 60. In an exemplary embodiment the gap 50 may be about a 1.0-millimeter gap 50. There may be from one to four servers 70 mounted on each of the seventy-two server blades 60.

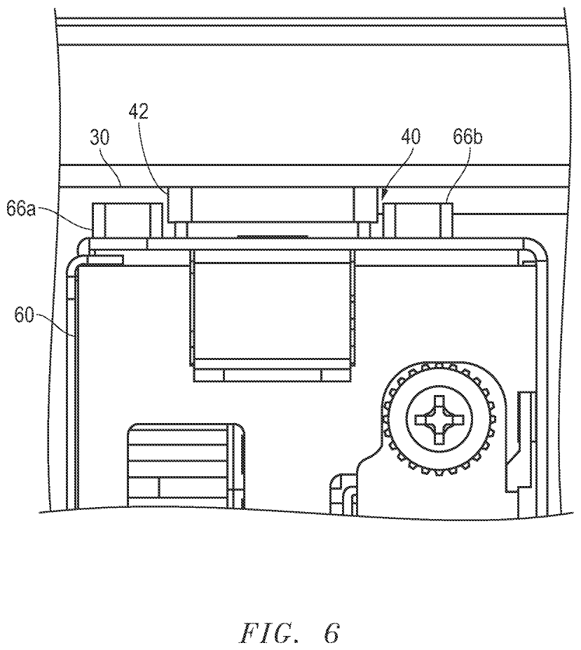

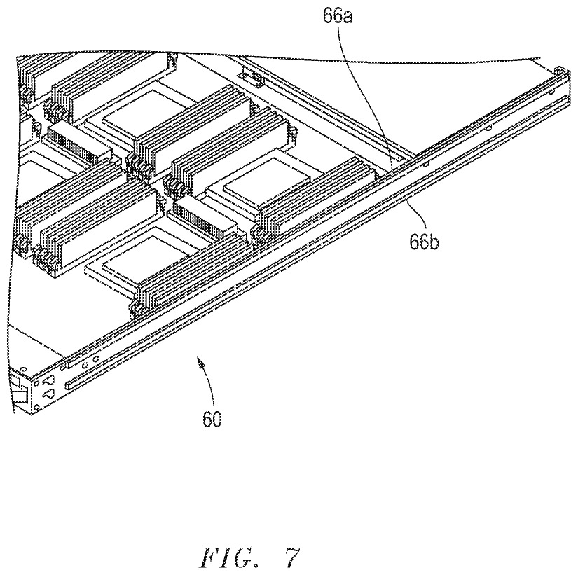

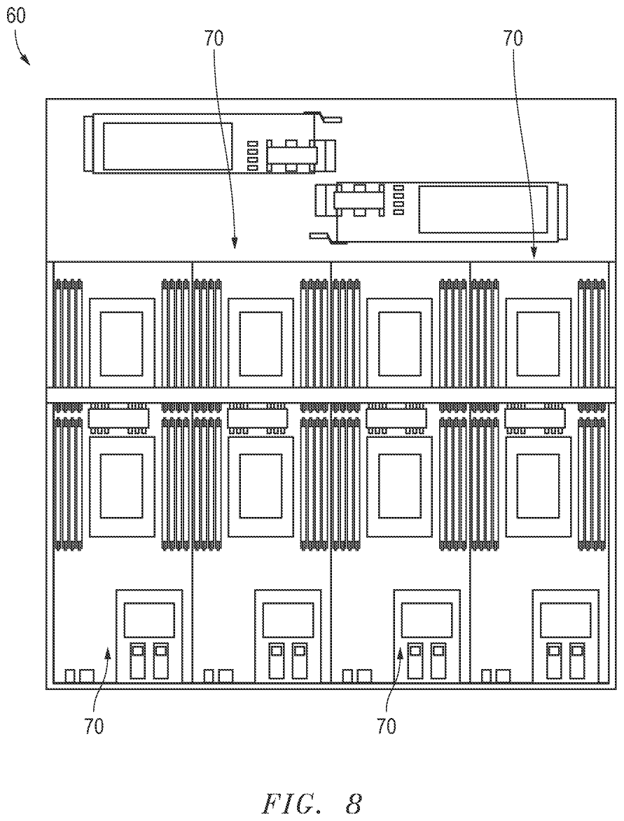

FIGS. 7-8 depict an exemplary embodiment of a blade 60. The blade 60 has two opposite sidewalls 65 including an outwardly projecting first track 66a and a complimentary outwardly projecting second track 66b for sliding each blade 60 into a bay 30 over a guide rail 42 (i.e., the guide rail 42 is interposed between the first track 66a and its complimentary second track 66b). See also FIG. 6. The exemplary embodiment of the blade 60 of FIG. 8 has four servers 70 mounted thereon. The blade 60 may be made with heat sinks (not shown) removed. The heat sinks may be removed due to the efficiency of thermal heat removal via the fluid 80 circulating and being cooled in the two-phase fluid immersion cooling tank 20. It is to be understood that current heat sink designs can create challenges or problems as to minimizing the overall space required on the blade 60 for servers 70 or, in effect, to maximize the density of servers 70 that can be fit onto a blade 60 and into a bay 30.

A modular apparatus for two-phase fluid immersion cooling of a plurality of servers in a datacenter facility may be shipped to a data center location, for example, by truck or train. A modular apparatus for two-phase fluid immersion cooling of a plurality of servers in a datacenter may be rated for an IT load capacity of 500KEW to support High-Performance Compute clusters.

While the exemplary embodiments are described with reference to various implementations and exploitations, it will be understood that these exemplary embodiments are illustrative and that the scope of the inventive subject matter is not limited to them. Many variations, modifications, additions and improvements are possible.

Plural instances may be provided for components, operations or structures described herein as a single instance. In general, structures and functionality presented as separate components in the exemplary configurations may be implemented as a combined structure or component. Similarly, structures and functionality presented as a single component may be implemented as separate components. These and other variations, modifications, additions, and improvements may fall within the scope of the inventive subject matter.

1. An apparatus for two-phase fluid immersion cooling of a plurality of servers in a datacenter facility, comprising:
a tank comprising a rectangular base and four sidewalls perpendicular to the base, wherein two of the four sidewalls are relatively shorter sidewalls, wherein the four sidewalls form a rectangular shaped compartment, and wherein the four sidewalls define a top-side opening;
a plurality of bays mounted in the rectangular shaped compartment of the tank;
a plurality of guide rail systems one each respectively mounted in each of the plurality of bays, wherein each of the guide rail systems comprises eighteen guide rails mounted on two opposite inner surfaces of each of the bays, wherein each of the eighteen guide rails is mounted having one of two longest dimensions vertically positioned and another of the two longest dimensions is mounted perpendicular to the direction of the two relatively shorter sidewalls, wherein each of the eighteen guide rails is mounted in parallel to an adjacent guide rail;
seventy-two server blades, wherein each server blade is separately and respectively mounted in each of the guide rails, wherein each of the server blades defines a gap between the adjacent server blade;
at least one server mounted on each of the seventy-two server blades;
a volume of a two-phase immersion cooling fluid in each of the plurality of bays wherein each of the eighteen server blades per bay is immersed in the volume of two-phase immersion cooling fluid;
wherein the tank further comprises a circulating system;
wherein the circulating system comprises a circulation pump mounted to the tank for circulating the volume of two-phase immersion cooling fluid, and a filtration system mounted to the tank for filtering the volume of two-phase immersion cooling fluid;
wherein the tank further comprises a cooling system;
wherein the cooling system comprises a condensing system mounted inside the rectangular shaped compartment of the tank and above the volume of two-phase immersion cooling fluid in each of the plurality of bays.

2. The apparatus for two-phase fluid immersion cooling of the plurality of servers in the data center facility according to claim 1, wherein a plurality of servers are mounted on each of the seventy-two server blades.

3. The apparatus for two-phase fluid immersion cooling of the plurality of servers in the data center facility according to claim 1, wherein the gap defined by each of the server blades is about a 1.0-millimeter gap.

4. The apparatus for two-phase fluid immersion cooling of the plurality of servers in the data center facility according to claim 2, wherein four servers are mounted on each of the seventy-two server blades.

5. The apparatus for two-phase fluid immersion cooling of the plurality of servers in the data center facility according to claim 4, wherein the gap defined by each of the server blades is about a 1.0-millimeter gap.

6. The apparatus for two-phase fluid immersion cooling of the plurality of servers in the data center facility according to claim 2, wherein two servers are mounted on each of the seventy-two server blades.

7. The apparatus for two-phase fluid immersion cooling of the plurality of servers in the data center facility according to claim 6, wherein the gap defined by each of the server blades is about a 1.0-millimeter gap.

8. The apparatus for two-phase fluid immersion cooling of the plurality of servers in the data center facility according to claim 1, wherein the plurality of bays comprises four bays.

9. An apparatus for two-phase fluid immersion cooling of a plurality of servers in a datacenter facility, comprising:
a tank comprising a rectangular base and four sidewalls perpendicular to the base, wherein two of the four sidewalls are relatively shorter sidewalls, wherein the four sidewalls form a rectangular shaped compartment, and wherein the four sidewalls define a top-side opening;
four bays mounted in the rectangular shaped compartment of the tank;
a plurality of guide rail systems one each respectively mounted in each of the four bays, wherein each of the guide rail systems comprises eighteen guide rails mounted on two opposite inner surfaces of each of the bays, wherein each of the eighteen guide rails is mounted having one of two longest dimensions vertically positioned and another of the two longest dimensions is mounted perpendicular to the direction of the two relatively shorter sidewalls, wherein each of the eighteen guide rails is mounted in parallel to an adjacent guide rail;
seventy-two server blades, wherein each server blade is separately and respectively mounted in each of the guide rails, wherein each of the server blades defines a gap of about 1.0 millimeter between the adjacent server blade;
four servers mounted on each of the seventy-two server blades;
a volume of a two-phase immersion cooling fluid in each of the four bays wherein each of the eighteen server blades per bay is immersed in the volume of two-phase immersion cooling fluid;
wherein the tank further comprises a circulating system;
wherein the circulating system comprises a circulation pump mounted to the tank for circulating the volume of two-phase immersion cooling fluid, and a filtration system mounted to the tank for filtering the volume of two-phase immersion cooling fluid;
wherein the tank further comprises a cooling system;
wherein the cooling system comprises a condensing system mounted inside the rectangular shaped compartment of the tank and above the volume of two-phase immersion cooling fluid in each of the four bays.

10. A method of maximizing server density in a datacenter facility utilizing a two-phase immersion cooling system for cooling a plurality of servers, comprising the steps of:
mounting four bays in a rectangular tank;
mounting a guide rail system having eighteen guide rail slots in parallel in each of the four bays;
vertically positioning one of two longest dimensions of each guide rail slot and arranging another of the two longest dimensions to be perpendicular to a direction of two relatively shorter sidewalls of the rectangular tank;
filling each bay with a volume of two-phase immersion cooling fluid;
mounting a server blade having at least one server in each guide rail slot; and
each server blade defining a gap between an adjacent server blade.

11. The method according to claim 10, wherein the gap is about a 1.0-millimeter gap.
